(19) United States
(12) Patent Application Publication
(10) Pub. No.: US 2025/0323489 A1
(43) Pub. Date: Oct. 16, 2025

(54) CIRCUIT ARRANGEMENT FOR CONTROLLING AN ELECTRONIC FUSE AND METHOD FOR OPERATING SUCH A CIRCUIT ARRANGEMENT

(71) Applicant: Conti Temic microelectronic GmbH, Ingolstadt (DE)

(72) Inventors: Erwin Kessler, Saulgau (DE); Bernd Ingo Scheier, Horgenzell (DE)

(73) Assignee: Conti Temic microelectronic GmbH, Ingolstadt (DE)

(21) Appl. No.: 19/093,771

(22) Filed: Mar. 28, 2025

(30) Foreign Application Priority Data
Apr. 15, 2024 (DE) 10 2024 203 476.2

(51) Int. Cl. H02H 3/08; G01R 19/165; G01R 31/58; H02H 1/00

(52) U.S. Cl. CPC H02H 3/08; G01R 19/16571; G01R 31/58; H02H 1/0092

(57) ABSTRACT

A circuit arrangement is described having a controllable electronic fuse which is arranged in a load path and whose control input is connected to a logic circuit, having a microcontroller which is formed with at least one central processing unit, with at least one read-only memory in electrical communication therewith and at least one analog-digital converter, having a current measuring device which is configured to record the current through the load path and is connected to the at least one analog-digital converter for transmitting the recorded current values, and having a comparator connected to the at least one analog-digital converter for receiving the recorded and digitized current values, to the microcontroller for receiving current limit values and to the logic circuit for transmitting control signals.

### BRIEF DESCRIPTION OF THE DRAWINGS

The disclosure is explained in more detail below based on exemplary embodiments with the aid of figures, in which:

FIG. 1 shows a basic circuit diagram of an exemplary circuit arrangement for controlling an electronic fuse;

FIG. 2 shows an alternative basic circuit diagram of an exemplary circuit arrangement for controlling an electronic fuse in a first operating mode;

FIG. 3 shows the alternative basic circuit diagram of FIG. 2 in a second exemplary operating mode;

FIG. 4 shows a time-current intensity diagram of exemplary switching states of an exemplary electronic fuse in the first operating state; and

FIG. 5 shows a time-current intensity diagram of exemplary switching states of an exemplary electronic fuse in a second operating state.

### DETAILED DESCRIPTION

The disclosure relates to a circuit arrangement having a controllable electronic fuse which is arranged in a load path and whose control input is connected to a logic circuit. The logic circuit is controlled by a comparator which receives digitized measured values of the current through the load path from an analog-digital converter and switches off the electronic fuse if a predefined limit value is exceeded by the current.

Such a circuit arrangement is known from DE 10 2019 119 972 B3. There, the circuit arrangement having the analog-digital converter, the comparator and the logic circuit is preferably integrated in an integrated circuit which can be controlled by a microcontroller.

In new vehicle architectures, the conventional battery voltage distributors having safety fuses are being replaced with zone controller assemblies having semiconductor-based intelligent fuses (eFuses). In addition to further functionalities, these electronic fuses, like the safety fuses, have the task of protecting the outgoing supply lines against overload.

Electronic fuses with a maximum driver capability, which exceeds the maximum current carrying capacity of the connected line, are usually implemented using special semiconductor switches with an integrated cable protection function.

More cost-effective solutions are based on so-called standard semiconductor switches without this cable protection function, which, however, usually have a measurement function for the switched output current. Based on this measured current, the cable protection function is then calculated in an evaluation unit (microcontroller). If a line overload is determined, the semiconductor switch of the electronic fuse is then deactivated.

A problem with this more cost-effective solution arises during the time of a software update of the evaluation unit or the microcontroller. The corresponding read-only memory—usually a flash EEPROM—is written to using a special software package (boot loader) which is intended to be kept very simple.

During the write process, no other programs or functions should be executed with the central processing unit of the microcontroller or memory involvement in addition to this reprogramming of the computer unit.

The electronic fuses, which require a cable protection function, are generally used to supply voltage to control devices which then control actuators. The high current requirement on the relevant supply line generally results from the current requirement of the actuators. The current requirement of the control unit is usually not critical with regard to the current carrying capacity of the supply line. Since there is no actuator control during the write or reprogramming process, the line protection function can be significantly simplified in this limited time.

In addition to at least one central processing unit and at least one read-only memory, microcontrollers used in motor vehicles have peripheral units, such as analog-digital converters and timer units. This is described, for example, in the data sheet for Infineon's TC1796 (e.g. https://www.infineon.com/cms/de/product/microcontroller/legacy-microcontroller/other-legacy-mcus/audo-family/tc1796-audo-nextgeneration/sak-tc1796-256f150e-be/).

The object of the disclosure is a circuit arrangement and a method which enable this simplified cable protection function during a process of writing to a read-only memory of a microcontroller without the involvement of the central processing unit or the read-only memory.

The object is achieved by means of a circuit arrangement having a controllable electronic fuse which is arranged in a load path and whose control input is connected to a logic circuit, having a microcontroller which is formed with at least one central processing unit, with at least one read-only memory in electrical communication therewith and at least one analog-digital converter, having a current measuring device which is configured to record the current through the load path and is connected to the at least one analog-digital converter for transmitting the recorded current values, and having a comparator connected to the at least one analog-digital converter for receiving the recorded and digitized current values, to the microcontroller for receiving current limit values and to the logic circuit for transmitting control signals.

The analog-digital converter already contained in a microcontroller is therefore advantageously used to digitize the determined values of the current through the load path in order to be able to compare them with a threshold value by means of a digital comparator in order to be able to switch off the electronic fuse on the basis thereof in the event of an overcurrent.

In one design of the circuit arrangement, the logic circuit may be part of the microcontroller. In this way, only an output of the microcontroller that controls the electronic fuse can be reset in a simple manner in order to turn off the fuse.

In one embodiment of the circuit arrangement, a plurality of load paths each with at least one electronic fuse may be advantageously connected to the microcontroller for controlling the electronic fuses by means of one or more analog-digital converters of the microcontroller. The circuit arrangement is therefore suitable for also protecting a plurality of load paths against an overcurrent.

The comparator or a plurality of comparators can also be parts of the microcontroller. This also simplifies the circuit and saves space on the printed circuit board.

The object of the disclosure is also achieved by means of a method for operating a circuit arrangement described above, in which, before starting to control a process of writing to the read-only memory, a current limit value for the load path is determined by the central processing unit of the microcontroller and is transmitted to the comparator for its initialization, in which, also before starting to control the write process, a recording of current values through the load path that is independent of the central processing unit is then started, and only then is the write process started. If the recorded current measured value exceeds the configured limit value, control of the electronic fuse is interrupted independently of the central processing unit via the logic circuit and the electronic fuse is thus turned off.

The circuit arrangement is thus advantageously used when the central processing unit of the microcontroller is not intended to be available for other tasks due to the reprogramming of the read-only memory.

In this case, if the logic circuit is part of the microcontroller, a microcontroller output, which controls the electronic fuse, can be reset if an overcurrent is detected. This can be done optionally for the output that controls the electronic fuse of the load path in which the overcurrent was detected.

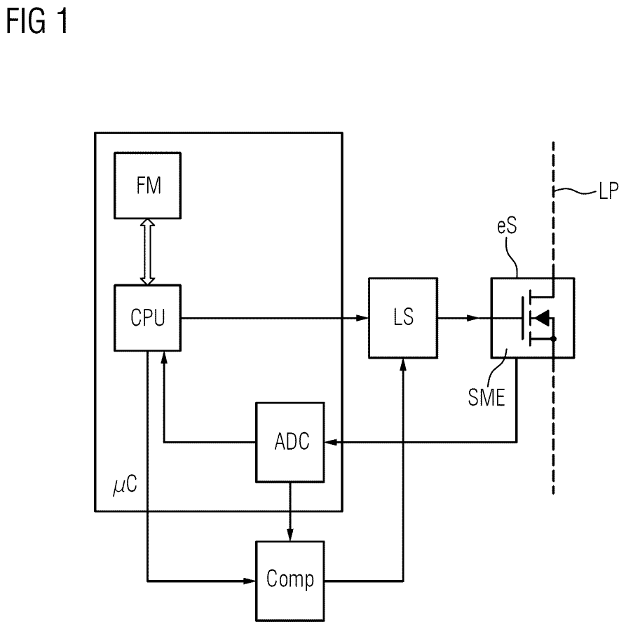

FIG. 1 shows a circuit arrangement having a controllable electronic fuse eS which is arranged in a load path LP and whose control input is connected to a logic circuit LS. The load path LP can be a supply line for a control device in a vehicle that is intended to be protected against an overcurrent via a fuse. The control device may be provided to control actuators, in particular to supply them with energy. Depending on the application, a larger current can flow for this purpose and must be provided via the load path LP.

The circuit arrangement has a microcontroller uC which is formed with at least one central processing unit CPU, with at least one read-only memory FM in electrical communication therewith and at least one analog-digital converter ADC. Such microcontrollers uC are known. They can also have a plurality of central processing units (multi-core processors) and a plurality of analog-digital converters, as well as other peripheral units such as timers. They can also contain a plurality of memories, in particular read-only memories. Read-only memories are currently commonly flash EEPROM memories. These read-only memories usually store the control software which may need to be updated. This requires special software called a boot loader.

The circuit arrangement further has a current measuring device SME which is configured to record the current through the load path LP and is connected to the at least one analog-digital converter ADC for transmitting the recorded current values. The analog-digital converter ADC is also connected to the central processing unit CPU in order to be able to transmit the digitized current values to the latter. The current measuring device may be formed in a known manner with a sense FET, or with a shunt resistor or a current mirror circuit or something similarly suitable.

A comparator Comp is provided and is connected to the at least one analog-digital converter ADC for receiving the recorded and digitized current values, to the central processing unit CPU via a line config for receiving current limit values and to the logic circuit LS for transmitting control signals.

Both the logic circuit LS and the comparator Comp or a plurality of comparators can be parts of the microcontroller uC, that is to say can be integrated on the same semiconductor chip. They can be operated independently of the central processing unit CPU of the microcontroller uC.

Without this being shown in FIG. 1, a plurality of load paths LP each with at least one electronic fuse eS can be connected to the microcontroller pC for controlling the electronic fuses eS by means of one or more analog-digital converters ADC of the microcontroller uC.

The circuit arrangement can be advantageously operated with a method in which, before starting to control a process of writing to the read-only memory, a current limit value for the load path LP is determined by the central processing unit CPU of the microcontroller uC and is transmitted to the comparator Comp for its initialization. Also before starting to control the write process, a recording of current values through the load path LP that is independent of the central processing unit CPU is started after this step, and only then is the write process started. If the recorded current measured value exceeds the configured limit value, control of the electronic fuse eS is interrupted independently of the central processing unit CPU via the logic circuit LS and the electronic fuse eS is thus turned off.

A microcontroller output, which controls the electronic fuse eS, can be reset in a simple way if the logic circuit LS is integrated in the microcontroller uC.

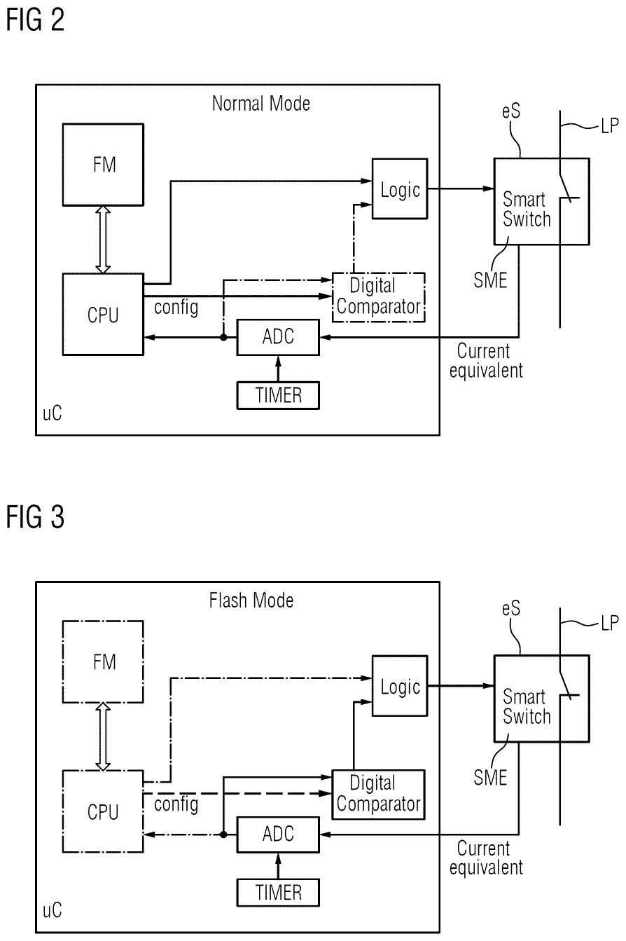

FIGS. 2 and 3 show two operating states of an alternative circuit arrangement in which the logic circuit LS is part of the microcontroller uC. FIG. 2 shows the “normal mode” in which the central processing unit CPU controls the electronic fuse eS by evaluating the current values from the current measuring device SME that are digitized by the analog-digital converter ADC and, depending on this, controlling the electronic fuse eS via the logic circuit LS.

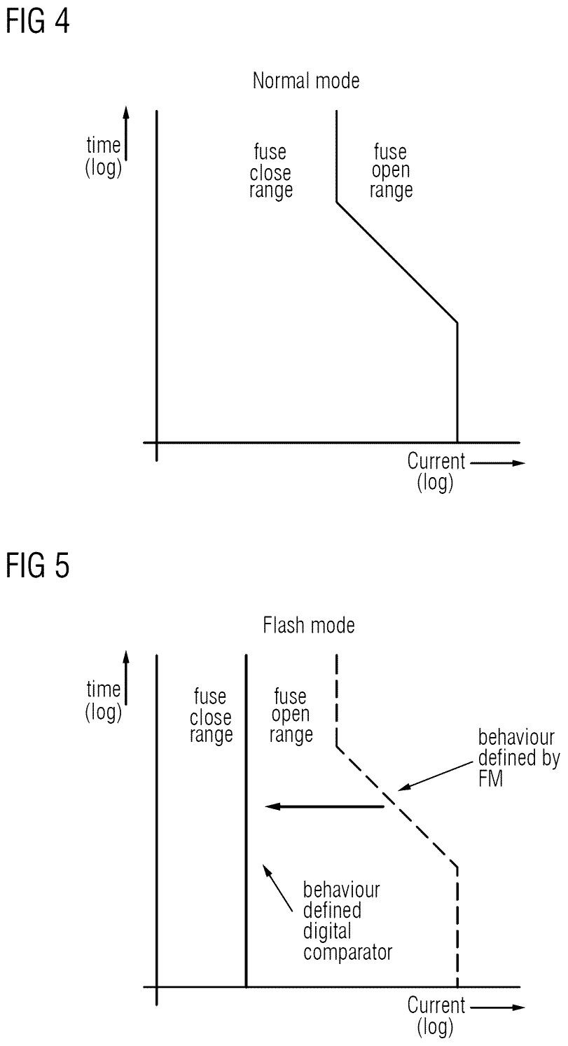

In this case, according to FIG. 4, not only the current intensity can be taken into account, but also the time during which a current of certain intensity flows, that is to say a safety fuse can be simulated. This is possible due to the higher computing power of the central processing unit CPU.

If the central processing unit CPU controls the programming of the read-only memory FW, and in this case is not intended to be available for further operations, which is shown schematically in FIG. 3, the comparator Comp assumes the task of monitoring the current intensity. This is carried out according to FIG. 5 in a much simpler way by comparing the determined and digitized current values only with a possibly lower current limit value and switching off the electronic fuse eS depending on this.

1. A circuit arrangement comprising:
a controllable electronic fuse arranged in a load path, whose control input is connected to a logic circuit,
a microcontroller with at least one central processing unit, with at least one read-only memory in electrical communication therewith and at least one analog-digital converter,
a current measuring device configured to record current through the load path connected to the at least one analog-digital converter for transmitting recorded current values, and
a comparator connected to the at least one analog-digital converter for receiving recorded and digitized current values, to the microcontroller for receiving current limit values, and to the logic circuit for transmitting control signals.

2. The circuit arrangement as claimed in claim 1, wherein a plurality of load paths each with at least one electronic fuse are connected to the microcontroller for controlling the electronic fuses via at least one analog-digital converter of the microcontroller.

3. The circuit arrangement as claimed in claim 1, wherein the comparator is part of the microcontroller.

4. The circuit arrangement as claimed in claim 1, wherein the logic circuit is part of the microcontroller.

5. The circuit arrangement as claimed in claim 4, wherein a plurality of load paths, each with at least one electronic fuse, is connected to the microcontroller for controlling the electronic fuses via at least one analog-digital converter of the microcontroller.

6. The circuit arrangement as claimed in claim 4, wherein the comparator is part of the microcontroller.

7. A method for operating the circuit arrangement as claimed in claim 1, wherein, prior to starting the write process:
before starting to control a write process to the read-only memory, a current limit value for the load path is determined by the central processing unit of the microcontroller and is transmitted to the comparator for its initialization, and
before starting to control the write process, a recording of current values through the load path that is independent of the central processing unit is started, if the comparator determines that at least one of the recorded current values exceeds the current limit value, control of the electronic fuse is interrupted independently of the central processing unit via the logic circuit and the electronic fuse is thus turned off.

8. The method as claimed in claim 7, wherein a plurality of load paths, each with at least one electronic fuse, is connected to the microcontroller for controlling the electronic fuses via at least one analog-digital converter of the microcontroller.

9. The method as claimed in claim 8, wherein a microcontroller output, which controls the electronic fuse, is reset.

10. The method as claimed in claim 9, wherein, if a process of writing to the read-only memory is not intended to be controlled by the central processing unit of the microcontroller, the central processing unit, instead of the comparator, evaluates the digital current values provided by the analog-digital converter and recorded in the load path, and controls the logic circuit.

11. The method as claimed in claim 7, wherein the comparator is part of the microcontroller.

12. The method as claimed in claim 11, wherein the comparator is part of the microcontroller and a microcontroller output, which controls the electronic fuse, is reset.

13. The method as claimed in claim 12, wherein, if a process of writing to the read-only memory is not intended to be controlled by the central processing unit of the microcontroller, the central processing unit, instead of the comparator, evaluates the digital current values provided by the analog-digital converter and recorded in the load path, and controls the logic circuit.

14. The method as claimed in claim 7, wherein, if a process of writing to the read-only memory is not intended to be controlled by the central processing unit of the microcontroller, the central processing unit, instead of the comparator, evaluates the digital current values provided by the analog-digital converter and recorded in the load path, and controls the logic circuit.

15. The method as claimed in claim 7, wherein the logic circuit is part of the microcontroller.

16. The method as claimed in claim 15, wherein a microcontroller output, which controls the electronic fuse, is reset.

17. The method as claimed in claim 16, wherein, if a process of writing to the read-only memory is not intended to be controlled by the central processing unit of the microcontroller, the central processing unit, instead of the comparator, evaluates the digital current values provided by the analog-digital converter and recorded in the load path, and controls the logic circuit.
